(19) United States
(12) Patent Application Publication
(10) Pub. No.: US 2012/0147572 A1
(43) Pub. Date: Jun. 14, 2012

(54) ELECTRONIC DEVICE HAVING DUST BLOCKING PORTION

(75) Inventors: TING-TING ZHAO, Shenzhen City (CN); XIAO-HUI ZHOU, Shenzhen City (CN); MIN-LI LI, Shenzhen City (CN); HONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/187,460

(22) Filed: Jul. 20, 2011

(30) Foreign Application Priority Data
Dec. 10, 2010 (CN) 201010583189.3

(51) Int. Cl. H05K 5/03

(52) U.S. Cl. 361/752

(57) ABSTRACT

An exemplary electronic device includes a casing with a through hole defined in the casing, a printed circuit board received in the casing, a slide bar received in the casing, a cover board pivotally fixed on the casing and having a hook extending though the through hole and detachably hooking in the slide bar, and a blocking portion located between the through hole of the casing and the printed circuit board.

### BACKGROUND

1. Technical Field

The present disclosure relates to electronic devices, and particularly to an electronic device having a blocking portion to prevent direct entry of dust into the electronic device.

2. Description of Related Art

An electronic device, such as a DVD (Digital Video Disc) player, generally includes a casing, a cover pivotally fixed on the casing, a button embedded in the casing, a printed circuit board received in the casing, and a slide element located in the casing and engaging with the button. The casing defines a through hole therein. The cover usually has a hook extending through the through hole, and hooking in the slide element. However, when the through hole is exposed to the outer environment, dust may fall directly on the printed circuit board via the through hole. This may cause contamination or even short-circuiting of the printed circuit board.

What is needed, therefore, is an electronic device which can overcome the above-described problems.

### BRIEF DESCRIPTION OF THE DRAWINGS

Many aspects of the present electronic device can be better understood with reference to the following drawings. The components in the drawings are not necessarily drawn to scale, the emphasis instead being placed upon clearly illustrating the principles of the present electronic device. Moreover, in the drawings, like reference numerals designate corresponding parts throughout the several views.

FIG. 1 is an assembled, isometric view of an electronic device in accordance with an exemplary embodiment of the disclosure.

FIG. 2 is an exploded view of the electronic device of FIG. 1.

FIG. 3 is an enlarged view of a circled part III of FIG. 2.

FIG. 4 is an inverted, exploded view of the electronic device of FIG. 1, viewing all the parts from a rear of the electronic device.

FIG. 5 is an assembled view of a slide bar and a portion of a cover plate of the electronic device of FIG. 4, viewed from a front of the cover plate.

FIG. 6 is a cross section view of the electronic device of FIG. 1, taken along a line VI-VI thereof.

FIG. 7 is an enlarged view of a circled part VII of FIG. 6.

FIG. 8 is similar to FIG. 6, but showing the slide bar of the electronic device slid to a different position.

FIG. 9 is an enlarged view of a circled part IX of FIG. 8.

### DETAILED DESCRIPTION

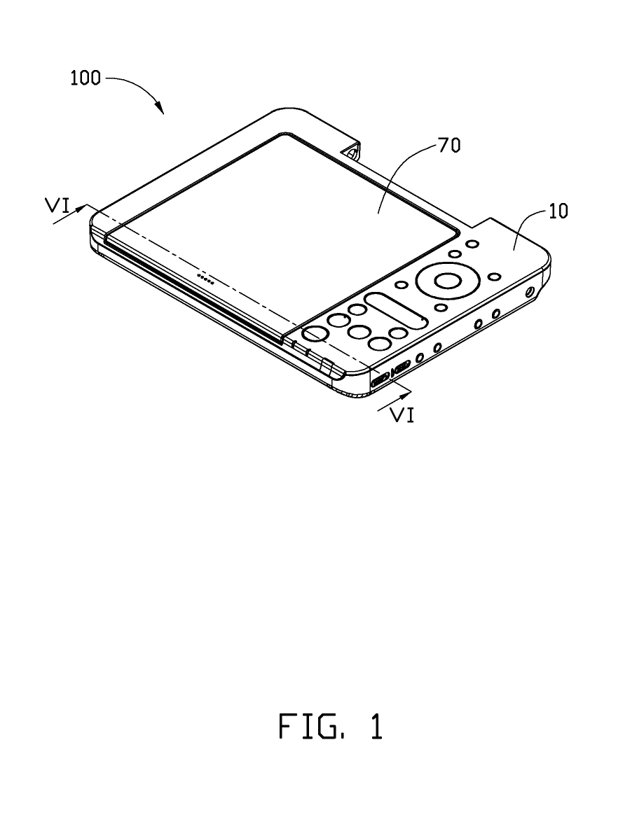

Referring to FIG. 1, an electronic device 100 in accordance with an exemplary embodiment of the disclosure is shown. The electronic device 100 comprises a mounting base 10, and a cover board 70 pivotally fixed on the mounting base 10. In this embodiment, the electronic device 100 is a DVD (Digital Video Disc) player. In this description, “front,” “rear,” “left” and “right” sides of the electronic device 100 are mentioned with reference to how the electronic device 100 appears in FIG. 1.

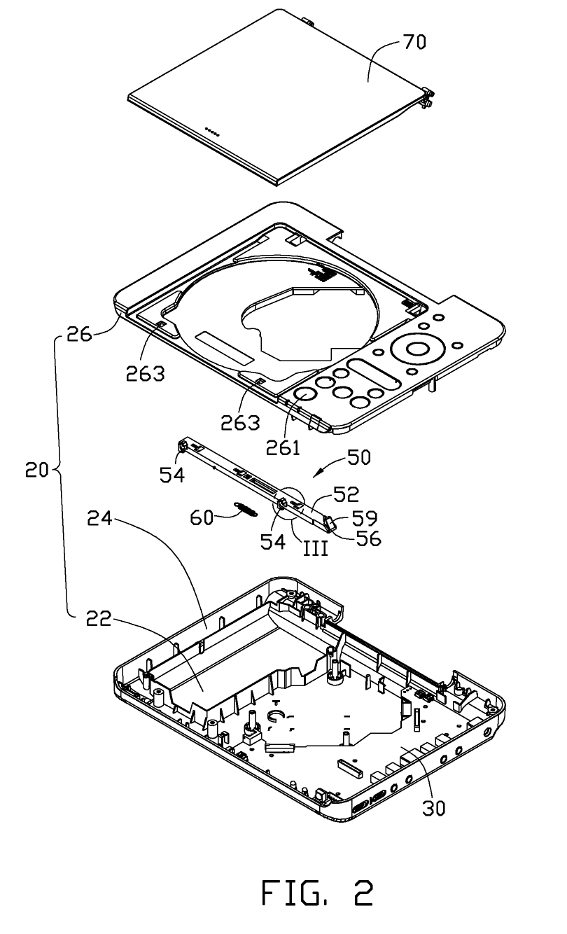

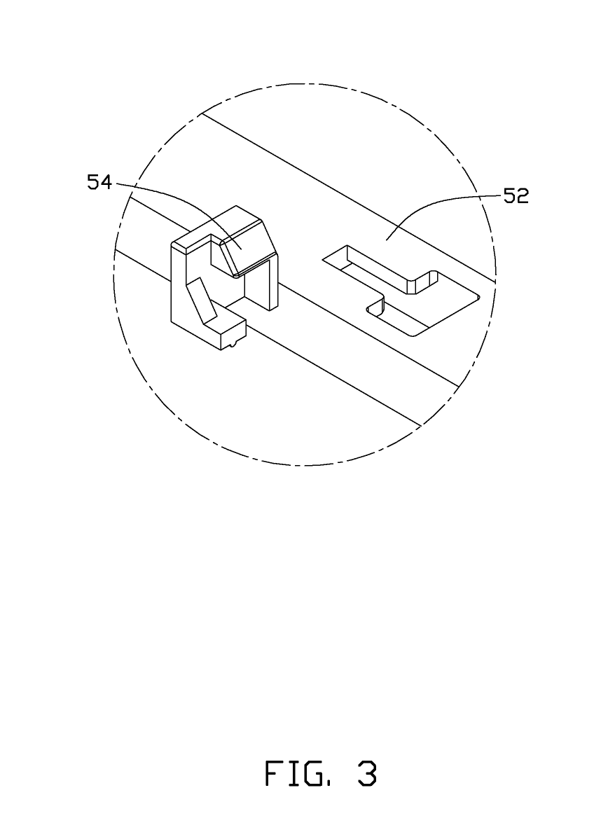

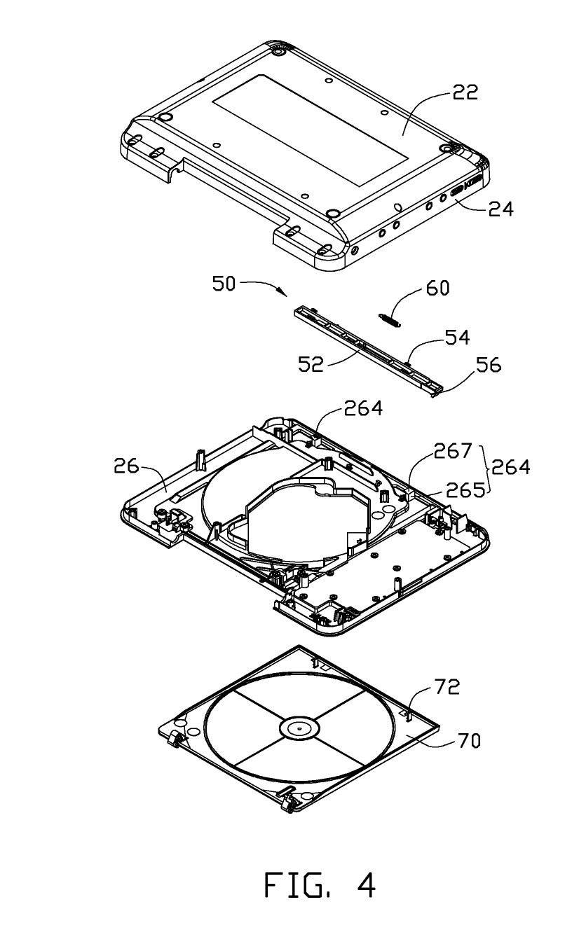

Referring to FIGS. 2-4 also, the mounting base 10 comprises a casing 20, a printed circuit board 30 received in the casing 20, and a slide bar 50 fixed in the casing 20. The casing 20 comprises a base plate 22, a frame-shaped sidewall 24 extending upwardly from an outer periphery of the base plate 22, and a cover plate 26. The printed circuit board 30 is fixed on the base plate 22.

The cover plate 26 has a rectangular profile. A receiving hole (not labeled) is defined in the cover plate 26 for receiving a button 261 therein. The button 261 is movable in an axial direction of the receiving hole of the cover plate 26. Two spaced through holes 263 are defined in the cover plate 26 adjacent to a lateral side, i.e. a front side, of the cover plate 26.

The cover board 70 has a rectangular profile. The cover board 70 is correspondingly placed on the cover plate 26 of the casing 20. Two spaced hooks 72 respectively protrude downwardly from the cover board 70 adjacent to a lateral side, i.e. a front side, of the cover board 70. The two hooks 72 are located corresponding to the two through holes 263 of the cover plate 26.

Two blocking portions 264 respectively protrude downwardly from a bottom face of the cover plate 26. Each blocking portion 264 comprises an L-shaped connecting section 265 extending downwardly from the bottom face of the cover plate 26, and a block section 267 bent perpendicularly from a bottom end of the connecting section 265. The block sections 267 of the blocking portions 264 correspondingly face toward the through holes 263. A dimension of each block section 267 is equal to or larger that that of the corresponding through hole 263. In this embodiment, the connecting section 265 of each blocking portion 264 is perpendicular to the cover plate 26, and the block section 267 is parallel to the cover plate 26.

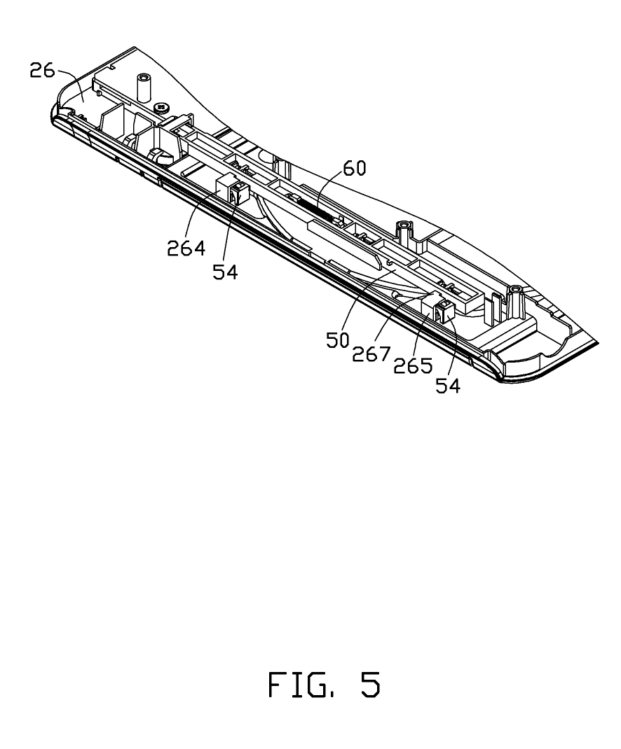

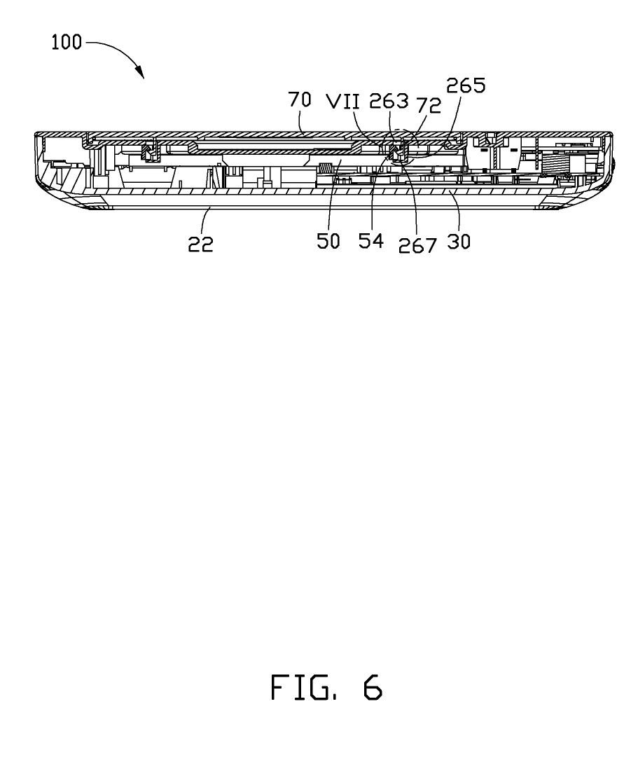

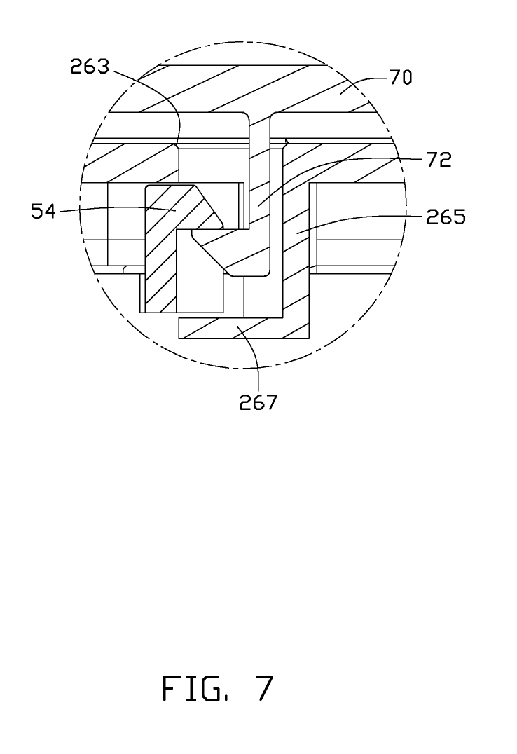

Referring to FIGS. 5-7 also, the slide bar 50 comprises an elongated main portion 52, two spaced locking portions 54 protruding outwardly from the main portion 52, a wedge-shaped engaging portion 56 extending outwardly from an end of the main portion 52, and a spring 60 fixed on the main portion 52. The slide bar 50 is fixed to the bottom face of the cover plate 26, and is able to be slid relative to the cover plate 26. Two ends of the spring 60 are respectively clamped at the main portion 52 and the cover plate 26. The spring 60 deforms resiliently and exerts a resilient force on the slide bar 50. The engaging portion 56 defines an inclined face 59, and a bottom of the button 261 abuts against the inclined face 59. The two hooks 72 of the cover board 70 are correspondingly extended through the through holes 263 of the cover plate 26, and hooked in the two locking portions 54, whereby the cover board 70 is secured on the base plate 26 of the casing 20.

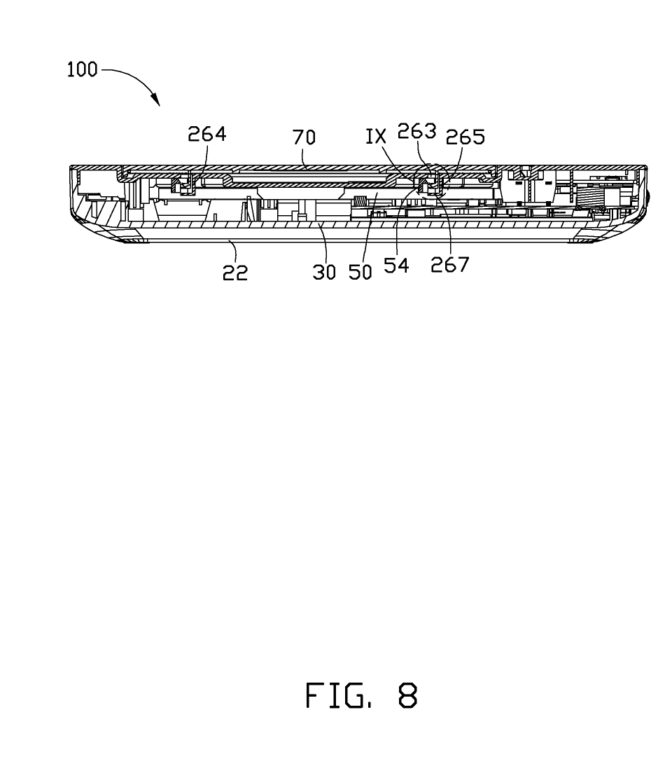

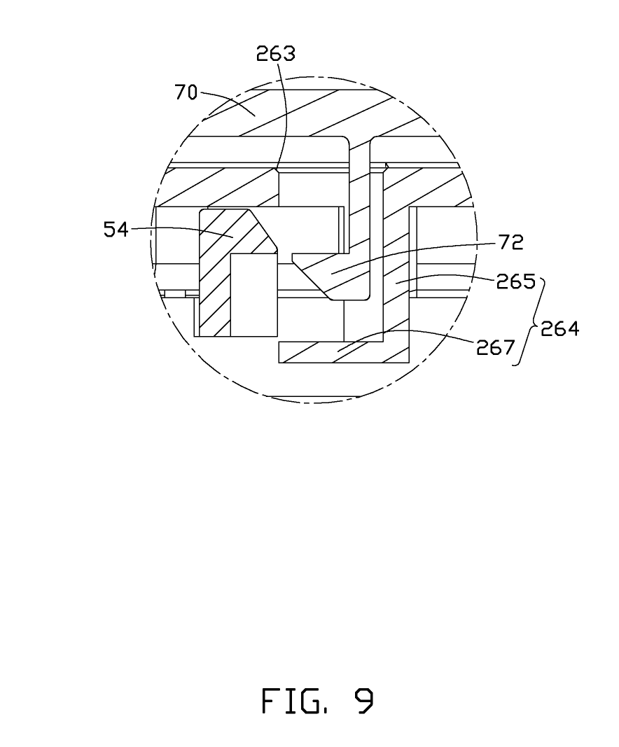

Referring to FIGS. 8-9 also, in use, when the button 261 is pressed downwardly, the engaging portion 56 of the slide bar 50 abutting against the bottom of the button 261 is pushed away, and the slide bar 50 is slid relative to the cover plate 26. The hooks 72 of the cover board 70 are released from the locking portions 54 of the slide bar 50, whereby the cover board 70 can be rotated away from the casing 20. When the through holes 263 are exposed to an outer environment, the blocking portions 264 facing toward the through holes 263 are located between the through holes 263 and the printed circuit board 30, thereby preventing dust directly falling on the printed circuit board 30 via the through holes 263.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
a casing defining a through hole;
a printed circuit board received in the casing;
a slide bar received in the casing;
a cover board pivotally fixed on the casing, the cover board having a hook extending though the through hole and detachably hooking with the slide bar; and
a blocking portion located between the through hole of the casing and the printed circuit board.

2. The electronic device of claim 1, wherein the casing comprises a base plate, a sidewall extending upwardly from an outer periphery of the base plate, and a cover plate.

3. The electronic device of claim 2, wherein the through hole is defined in the cover plate.

4. The electronic device of claim 3, wherein the blocking portion protrudes from a bottom face of the cover plate.

5. The electronic device of claim 4, wherein the blocking portion comprises a connecting section extending downwardly from the bottom face of the cover plate, and a block section bent perpendicularly from a bottom end of the connecting section, the block section facing toward the through hole.

6. The electronic device of claim 5, wherein a dimension of the block section is equal to or larger that that of the through hole.

7. The electronic device of claim 5, wherein the block section is parallel to the cover plate.

8. The electronic device of claim 5, wherein the connecting section is perpendicular to the cover plate.

9. The electronic device of claim 1, further comprising a button embedded in the casing adapted for engaging with the slide bar and making the slide bar to slide relative to the cover plate.

10. The electronic device of claim 9, wherein the slide bar comprises an elongated main portion, a locking portion protruding outwardly from the main portion and engaging with the hook of the cover board, a wedge-shaped engaging portion extending outwardly from an end of the main portion, and a spring fixed on the main portion.

11. The electronic device of claim 10, wherein the engaging portion defines an inclined face, and a bottom of the button abuts against the inclined face.

12. The electronic device of claim 10, wherein the spring deforms resiliently and exerts a resilient force on the slide bar, and two ends of the spring are respectively clamped at the main portion and the cover plate.

13. An electronic device comprising:
a casing defining a through hole;
a printed circuit board received in the casing;
a cover board pivotally fixed on the casing, the cover board having a hook extending though the through hole; and
a blocking portion comprising a connecting section extending downwardly from an inner face of the casing, and a block section bent from the connecting section, wherein the block section faces toward the through hole.

14. The electronic device of claim 13, wherein the casing comprises a base plate, an annular sidewall extending upwardly from an outer periphery of the base plate, and a cover plate.

15. The electronic device of claim 14, wherein the through hole is defined in the cover plate.

16. The electronic device of claim 15, wherein the blocking portion perpendicularly protrudes from a bottom face of the cove plate.

17. The electronic device of claim 15, wherein a dimension of the block section is equal to or larger that that of the through hole.

18. The electronic device of claim 15, wherein the block section is parallel to the cover plate.

19. The electronic device of claim 13, further comprising a slide bar received in the casing, and detachably engaging with the hook of the cover board.

20. The electronic device of claim 19, further comprising a button embedded in the casing adapted for engaging with the slide bar and making the slide bar to slide relative to the cover plate.
